(19) United States
(12) Patent Application Publication
(10) Pub. No.: US 2022/0084554 A1
(43) Pub. Date: Mar. 17, 2022

(54) MAGNETIC DISK DEVICE AND ERROR CORRECTION METHOD

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Syosuke MARUYAMA, Machida Tokyo (JP); Kana FURUHASHI, Kawasaki Kanagawa (JP)

(21) Appl. No.: 17/469,287

(22) Filed: Sep. 8, 2021

(30) Foreign Application Priority Data
Sep. 14, 2020 (JP) 2020-153964

(51) Int. Cl. G11B 20/18; G11B 20/12; G06F 11/10

(52) U.S. Cl. CPC G11B 20/1889; G11B 20/1258; G11B 20/1876; G11B 20/1833; G11B 2020/185; G06F 11/1004; G11B 2020/1241; G11B 2020/1289; G06F 11/1076

(57) ABSTRACT

According to one embodiment, a magnetic disk device includes a disk including a first area where user data is written and a second area which is different from the first area, a head configured to write data to the disk and read data from the disk, and a controller configured to generate, when a first sector of a first track, which includes a first parity sector and the first sector which is different from the first parity sector in the first area, is reassigned to a second track in the second area, a second parity sector corresponding to the first sector.

### CROSS-REFERENCE TO RELATED APPLICATIONS

This application is based upon and claims the benefit of priority from Japanese Patent Application No. 2020-153964, filed Sep. 14, 2020, the entire contents of which are incorporated herein by reference.

### FIELD

Embodiments described herein relate generally to a magnetic disk device and an error correction method.

### BACKGROUND

In recent years, magnetic disk devices having a technique that achieves high recording density have been developed. One type of the magnetic disk devices that achieves high recording density is, for example, a shingled magnetic recording type (shingled write magnetic recording: SMR, or shingled write recording: SWR) magnetic disk device, in which a plurality of tracks are overwritten in the radial direction of the disk. Note that, the magnetic disk devices may include an error correction function to correct read error based on a parity sector corresponding to a particular track.

### BRIEF DESCRIPTION OF THE DRAWINGS

FIG. 1 is a block diagram illustrating the structure of a magnetic disk device according to a first embodiment.

FIG. 2 is a schematic view of an example of a disk according to the first embodiment.

FIG. 3 is a schematic view of an example of a conventional magnetic recording process.

FIG. 4 is a schematic view of an example of a shingled magnetic recording process.

FIG. 5 is a schematic view of an example of an ECC process method for a track according to the first embodiment.

FIG. 6 is a schematic view of an example of the ECC process method for a track according to the first embodiment.

FIG. 7 is a schematic view of an example of the ECC process method for a track according to the first embodiment.

FIG. 8 is a schematic view of an example of the ECC process method for a track according to the first embodiment.

FIG. 9 is a flowchart of an example of the ECC process method of a reassigned track according to the first embodiment.

FIG. 10 is a flowchart of an example of the ECC process method of a source track according to the first embodiment.

FIG. 11 is a schematic view of an example of a generating method for a reassigned parity sector according to Modification 1.

FIG. 12 is a schematic view of an example of a generating method for a non-reassigned parity sector according to a second embodiment.

FIG. 13 is a schematic view of an example of an ECC processing method for a track according to the second embodiment.

FIG. 14 is a schematic view of a flowchart of an example of the ECC processing method for a source track according to the second embodiment.

### DETAILED DESCRIPTION

In general, according to one embodiment, a magnetic disk device comprises: a disk including a first area where user data is written and a second area which is different from the first area; a head configured to write data to the disk and read data from the disk; and a controller configured to generate, when a first sector of a first track, which includes a first parity sector and the first sector which is different from the first parity sector in the first area, is reassigned to a second track in the second area, a second parity sector corresponding to the first sector.

Hereinafter, some embodiments will be explained with reference to the accompanying drawings. Note that figures are merely examples, which do not limit the scope of the invention

### First Embodiment

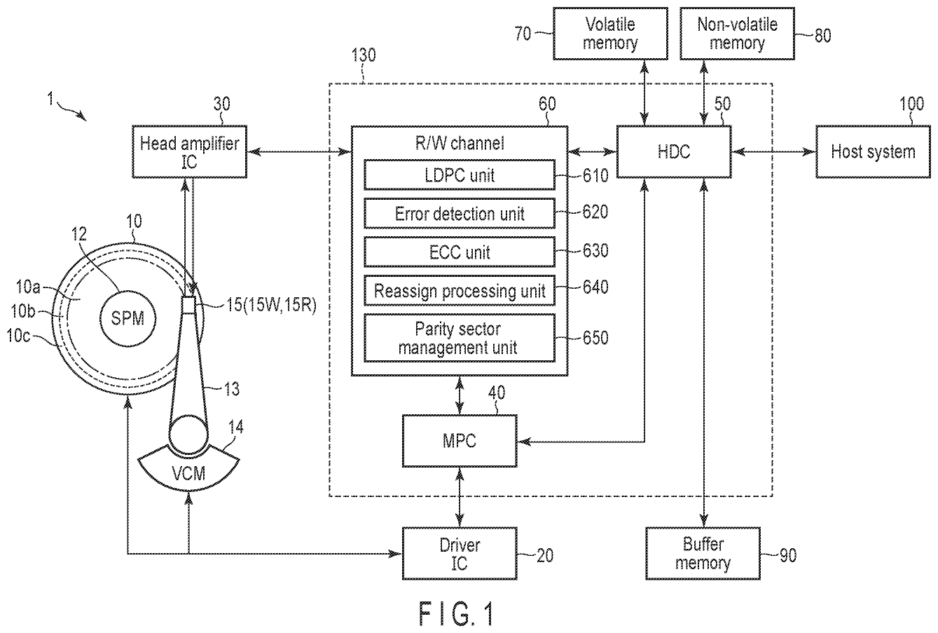

FIG. 1 is a block diagram illustrating the structure of a magnetic disk device 1 according to the first embodiment.

The magnetic disk device 1 includes a head disk assembly (HDA) which will be described later, driver IC 20, head amplifier integrated circuit (hereinafter may be referred to as head amplifier IC or preamplifier) 30, volatile memory 70, nonvolatile memory 80, buffer memory (buffer) 90, and system controller 130 as one-chip integrated circuit. The magnetic disk device 1 is connected to a host system (hereinafter referred to as host) 100.

The HDA includes a magnetic disk (disk) 10, spindle motor (SPM) 12, arm 13 on which a head 15 is mounted, and voice coil motor (VCM) 14. The disk 10 is attached to the SPM 12 to be rotated by the drive of the SPM 12. The arm 13 and the VCM 14 form an actuator. The actuator controls movement of the head 15, mounted on the arm 13, to a particular position of the disk 10, when the VCM 14 is driven. The number of the disks 10 and the heads 15 may be provided two or more.

The disk 10 includes a data writable area in which a user data region 10a which can be used by users, media cache (or media cache area) 10b which temporarily stores data (or command) transferred from a host or the like before writing the data in a particular area of the user data region 10a, and system area 10c where information necessary for the system management is written are allocated. Hereinafter, a direction from the inner circumference toward the outer circumference of the disk 10, or a direction from the outer circumference toward the inner circumference of the disk 10 is referred to as a radial direction. In the radial direction, a direction from the inner circumference to the outer circumference is referred to as outward direction (outer side), and a direction from the outer circumference to the inner circumference is referred to as inward direction (inner side). A direction orthogonal in the radial direction of the disk 10 is referred to as circumferential direction. The circumferential direction corresponds to a direction along the circumference of the disk 10. Furthermore, a particular position in the radial direction of the disk 10 may be referred to as a radial position, and a particular position in the circumferential direction of the disk 10 may be referred to as a circumferential position. The radial position and the circumferential position may be collectively referred to simply as a position. Note that a term track can be interpreted as various ways such as one area in a plurality of areas defined in the radial direction of the disk 10, path of the head 15 over a particular radial position, data extending in the circumferential direction of the disk 10, one-round data written in the track of a particular radial position, data written in a particular track of the disk 10, or partial data written in a particular track of the disk 10, for example. The term sector can be interpreted as various ways such as one area in a plurality of areas of a particular track of the disk 10 defined in the circumferential direction, data written in a particular circumferential position in a particular radial position of the disk 10, or data written in a particular sector of a particular track of the disk 10, for example. A width of the radial direction of the track may be referred to as track width. A path passing the center position of the track width in a particular track will be referred to as track center.

The head 15 includes a slider as the main body thereof, with a write head 15W and a read head 15R mounted on the slider. The write head 15W writes data to the disk 10. The read head 15R reads the data written in the disk 10. Note that the write head 15W may be referred to simply as head 15. Note that the read head 15R may be referred to simply as head 15. Note that the write head 15W and read head 15R may be collectively referred to simply as head 15. The center of the head 15 may be referred to as head 15, and the center of write head 15W may be referred to as write head 15W, and the center of read head 15R may be referred as read head 15R. The center of write head 15W may be referred to simply as head 15, and the center of read head 15R may be referred to simply as head 15. Positioning the center of the head 15 on the track center of a particular track may be referred to as positioning the head 15 on a particular track, arranging the head 15 on a particular track, or placing the head 15 to a particular track.

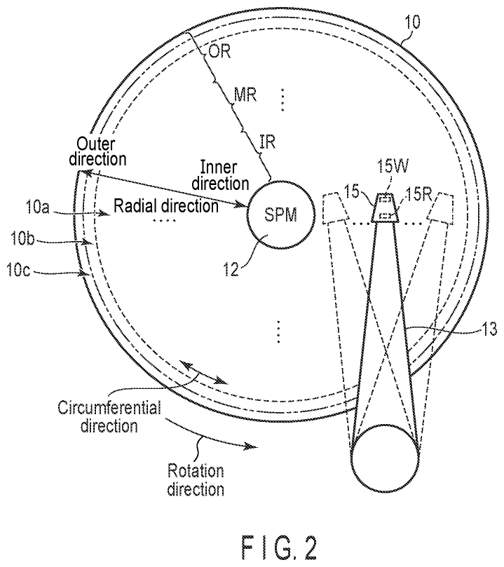

FIG. 2 is a schematic diagram of an example of the disk 10 according to the present embodiment. As shown in FIG. 2, the direction in which the disk 10 rotates in the circumferential direction will be referred to as rotation direction. In the example illustrated in FIG. 2, the rotation direction is depicted counterclockwise, but it may be in the opposite direction (clockwise). In FIG. 2, the disk 10 is divided into an inner circumference region IR located in the inward direction, an outer circumference region OR located in the outward direction, and a middle circumference region MR located between the inner circumference region IR and the outer circumference region OR.

In the example illustrated in FIG. 2, the disk 10 includes a user data region 10a, media cache 10b, and system area 10c. In FIG. 2, the user data region 10a, media cache 10b, and system area 10c are arranged outward in this order. In FIG. 2, the media cache 10b is located adjacent to the user data region 10a in the outward direction. In other words, the media cache 10b is located between the user data region 10a and the system area 10c. Here, adjacent means not only that data, objects, areas, and spaces are lined up in contact with each other, but also that they are lined up at intervals. In FIG. 2, the system area 10c is located adjacent to the media cache 10b in the outward direction. Note that the order in which the user data region 10a, media cache 10b, and system area 10c are arranged is not limited to the order of FIG. 2, but may be any order.

In the example illustrated in FIG. 2, the user data region 10a is located from the inner circumferential region IR to the outer circumferential region OR in the radial direction. In the example illustrated in FIG. 2, the media cache 10b is located in the outer circumference area OR in the radial direction. Note that the media cache 10b may be located in the inner circumferential region IR or the middle region MR. Furthermore, the media cache 10b may be positioned to be distributed in the outer circumferential region OR, the middle circumferential region MR, and the inner circumferential region IR. In the example illustrated in FIG. 2, the system area 10c is located in the outer circumferential region OR in the radial direction. In other words, the system area 10c is located from a particular position in the outer circumferential region OR to the outermost circumference of the disk 10. Note that the system area 10c may be located in the middle circumference area MR or the inner circumference area IR.

In the user data region 10a of the disk 10, data may be written in a shingled magnetic recording (Shingled Write Magnetic Recording: SMR, or Shingled Write Recording: SWR) mode where a track to be written next is overwritten on a part of the radial direction of a particular track. The “adjacent track” includes “a track adjacent to a particular track in the outward direction”, “an adjacent track in the inward direction of a particular track”, and “a plurality of tracks adjacent in an outward direction and an inward direction of a particular track. Note that, to the user data region 10a, data may be written in a track adjacent to a particular track in the radial direction (hereinafter may be referred to as an adjacent track) such that a particular interval therebetween, or may be written in a conventional magnetic recording (CMR) mode that allows random data writing. Hereinafter, “to write data in shingled magnetic recording mode” may be referred to as “to shingled magnetic record”, or “to perform shingled magnetic recording processing”, or “to write”. A write process other than the conventional magnetic recording process, may be shingled magnetic recording process. Furthermore, “to write data in the conventional magnetic recording mode” may be referred to as “to conventional magnetic record”, “to perform conventional magnetic recording processing”, or “to write”.

Data may be written to the media cache 10b and the system area 10c of the disk 10 in the conventional magnetic recording mode. Note that, data may be written to the media cache 10b and the system area 10c in the shingled magnetic recording mode.

As shown in FIG. 2, the head 15 is rotated around the rotation axis by the drive of VCM 14 with respect to the disk 10 to move from the inward direction to the outward direction to be arranged at a particular position, or to move from the outward direction to the inward direction to be arranged at a particular position.

The driver IC 20 controls the drive of SPM 12 and VCM 14 according to the control of the system controller 130 (specifically, MPU 60 to be described later).

The head amplifier IC (preamplifier) 30 includes, a read amplifier, a write driver, and like. The read amplifier amplifies the read signal read from the disk 10 and outputs the read signal to the system controller 130 (specifically, read/write (R/W) channel 40, which will be described later). The write driver outputs the write current according to the signal output from the R/W channel 40 to the head 15.

The volatile memory 70 is a semiconductor memory in which stored data is lost when the power supply is interrupted. The volatile memory 70 stores data, etc., necessary for processing in each part of the magnetic disk device 1. The volatile memory 70 is, for example, a dynamic random access memory (DRAM) or a synchronous dynamic random access memory (SDRAM).

The nonvolatile memory 80 is a semiconductor memory in which stored data is maintained even when the power supply is interrupted. The nonvolatile memory 80 is, for example, a NOR or NAND flash ROM (Flash Read Only Memory: FROM).

The buffer memory 90 is a semiconductor memory which temporarily stores data, etc., transferred/received between the magnetic disk device 1 and the host 100. The buffer memory 90 may be structured integrally with the volatile memory 70. The buffer memory 90 is, for example, DRAM, static random access memory (SRAM), SDRAM, ferroelectric random access memory (FeRAM), or magnetoresistive random access memory (MRAM).

The system controller (controller) 130 is realized, for example, using a large-scale integrated circuit (LSI) referred to as a System-on-a-Chip (SoC) in which multiple elements are integrated on a single chip. The system controller 130 includes a microprocessor (MPU) 40, hard disk controller (HDC) 50, and read/write (R/W) channel 60. The system controller 130 is electrically connected to, for example, the driver IC 20, head amplifier IC 30, volatile memory 70, nonvolatile memory 80, buffer memory 90, and host system 100.

The MPU 40 is the main controller configured to control each part of the magnetic disk device 1. The MPU 40 controls the VCM 14 via the driver IC 20 to execute servo control for positioning the head 15. The MPU 40 controls the SPM 12 via the driver IC 20 to rotate the disk 10. The MPU 40 controls the write operation of data to the disk 10 and selects a destination for the data transferred from the host 100, for example, the write data. The MPU 40 controls the read operation of data from the disk 10 and the processing of data transferred from the disk 10 to the host 100. The MPU 40 may perform the processing based on firmware. The MPU 40 is connected to each part of the magnetic disk device 1. For example, the MPU 40 is electrically connected to the driver IC 20, HDC 50, and R/W channel 60.

The MPU 40 executes the shingled magnetic recording process in the user data region 10a of the disk 10 according to the command from the host 100. Note that, the MPU 40 executes the conventional magnetic recording process in the user data region 10a. The MPU 60 executes the conventional magnetic recording process in the media cache 10b and the system area 10c of the disk 10. Note that the MPU 60 may also execute the shingled magnetic recording process in the media cache 10b and the system area 10c of the disk 10. In the following description, the term access may be may be interpreted as recording or writing data to a particular area, loading or reading data from a particular area, and moving the head 15 to a particular area, for example.

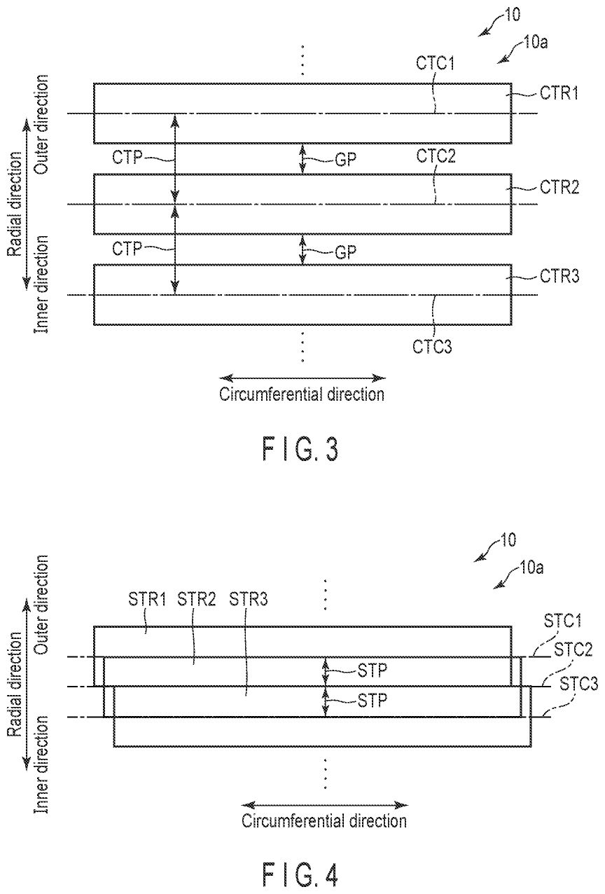

FIG. 3 is a schematic diagram of the conventional magnetic recording process. FIG. 3 illustrates tracks CTR1, CTR2, and CTR3. In FIG. 3, for example, the track widths of tracks CTR1, CTR2, and CTR3 are the same. Note that the track widths of tracks CTR1 to CTR3 may be different. Terms such as “same”, “identical”, “match”, and “equivalent” include the meaning of being exactly the same, as well as the meaning of being different to the extent that they can be considered to be substantially the same. FIG. 3 illustrates the track center CTC1 of track CTR1, the track center CTC2 of track CTR2, and the track center CTC3 of track CTR3. In the example of FIG. 3, tracks CTR1, CTR2, and CTR3 are written with a track pitch CTP. The track center CTC1 of track CTR1 and the track center CTC2 of track CTR2 are separated by the track pitch CTP. The track center CTC2 of track CTR2 and the track center CTC3 of track CTR3 are separated by the track pitch CTP. Track CTR1 and track CTR2 are separated by a gap GP. Note that tracks CTR1 to CTR3 may be lit with different track pitches. In FIG. 3, for convenience of explanation, each track is shown as a rectangle extending in the circumferential direction with a particular track width, but in reality, it is curved along the circumferential direction. Each track may also be wavy, extending in the circumferential direction while varying in the radial direction.

In the example of FIG. 3, the MPU 40 positions the head 15 at the track center CTC1 in a particular area of the disk 10, for example, user data region 10a, and performs conventional magnetic recording of the track CTR1 or a particular sector of the track CTR1. In the user data region 10a, the MPU 40 positions the head 15 at the track center CTC2, which is inwardly separated from the track center CTC1 of the track CTR1 by the track pitch CTP, and performs conventional magnetic recording of the track CTR2 or a particular sector of the track CTR2. In the user data region 10a, the MPU 40 positions the head 15 at the track center CTC3, which is inwardly separated from the track center CTC2 of the track CTR2 by the track pitch CTP, and performs the conventional magnetic recording of the track CTR3 or the specified sector of the track CTR3. The MPU 40 may sequentially perform conventional magnetic recording of tracks CTR1, CTR2, and CTR3 in a particular area of disk 10, for example, user data region 10a, or may randomly perform conventional magnetic recording of particular sectors of track CTR1, particular sectors of track CTR2, and particular sectors of track CTR3.

FIG. 4 is a schematic diagram illustrating an example of the shingled magnetic recording process. FIG. 4 illustrates a plurality of tracks STR1, STR2, and STR3 which are continuously overwritten in one direction in the radial direction. In the following description, in the shingled magnetic recording, the area where data is written by the write head 15W is referred to as write track, and the remaining area of a particular track other than the area where other write tracks are overwritten may be referred to as read track. FIG. 4 illustrates the track center STC1 of the track STR1 where no other track is overwritten, the track center STC2 of the track STR2 where no other track is overwritten, and the track center STC3 of track STR3 where no other track is overwritten. In the example of FIG. 4, tracks STR1, STR2, and STR3 are written with track pitch STP. The track center STC1 of track STR1 and the track center STC2 of track STR2 are separated by the track pitch STP. The track center STC2 of track STR2 and the track center STC3 of track STR3 are separated by the track pitch STP. Tracks STR1 to STR3 may be written with different track pitches. In FIG. 4, the width of the radial direction in the area where track STR2 is not overwritten in track STR1 and the width of the radial direction in the area where track STR3 is not overwritten in track STR2 are the same. Note that the width of the radial direction of the area in track STR1 where track STR2 is not overwritten and the width of the radial direction of the area in track STR2 where track STR3 is not overwritten may be different. In FIG. 4, for convenience of explanation, each track is shown as a rectangle extending in the circumferential direction with a particular track width, but in reality, it is curved along the circumferential direction. Furthermore, each track may also be wavy, extending in the circumferential direction while varying in the radial direction. In FIG. 4, three tracks are overwritten, but less than three or more than three tracks may be overwritten.

In the example illustrated in FIG. 4, the MPU 40 sequentially performs shingles magnetic recording of tracks STR1 to STR3 in the inward direction at track pitch STP. The MPU 40 may sequentially perform shingle magnetic recording of tracks STR1 to STR3 in the outward direction at track pitch STP. The MPU 40 writes track STR2 at track pitch STP in the inward direction of track STR1, and overwrites track STR2 on a part of the inward direction of track STR1. The MPU 40 writes track STR3 at track pitch STP in the inward direction of track STR2, and overwrites track STR3 on a part of the inward direction of track STR2.

The HDC 50 controls the transfer of data. For example, the HDC 50 controls the transfer of data between the host 100 and the disk 10 in response to an instruction from the MPU 40. The HDC 50 is electrically connected to, for example, the MPU 40, R/W channel 60, volatile memory 70, nonvolatile memory 80, and buffer memory 90.

The R/W channel 60 performs signal processing of data transferred from the disk 10 to the host 100 (hereinafter may be referred to as read data) and data transferred from the host 100 (hereinafter may be referred to as write data) in response to instructions from the MPU 40. The R/W channel 60 includes a circuit or a function to measure signal quality of the read data. The R/W channel 60 is electrically connected to, for example, the head amplifier IC 30, MPU 40, and HDC 50.

The R/W channel 60 includes, for example, a low density parity check (LDPC) part 610, error detection unit 620, error correction code (ECC) unit 630, reassign control unit 640, and parity sector management unit 650. The MPU 60 may execute each of the parts, for example, the LDPC unit 610, error detection unit 620, ECC unit 630, reassign control unit 640, and parity sector management unit 650 on firmware or may include them as circuits. The LDPC unit 610, error detection unit 620, ECC unit 630, reassign control unit 640, and parity sector management unit 650 may be provided with the MPU 40 or HDC 50, or in other parts of the system controller 130.

The LDPC unit 610 performs LDPC processing (or may be referred to as LDPC correction processing). The LDPC unit 610 performs LDPC correction processing to correct errors in data based on LDPC codes. Hereinafter, “process of error correction in data” may be referred to as “error correction process”. Furthermore, “to correct error in data” may be referred to as “to correct error”.

The error detection unit 620 detects data, a sector, areas, and like with an error. For example, the error detection unit 620 detects data that cannot be read or cannot be read even after repeating the read operation a particular number of times (hereinafter may be referred to as read error data) or a sector that cannot be read or cannot be read even after repeating the read operation a particular number of times (hereinafter may be referred to as a read error sector). For example, the error detection unit 620 detects read error data or a read error sector that cannot be corrected by LDPC correction processing. Furthermore, the error detection unit 620 detects read error data that cannot be corrected by LDPC correction processing or a read error sector that cannot be corrected by LDPC correction processing based on detection (or inspection) codes, for example, parity inspection codes. Hereinafter, “read error data that cannot be corrected by the LDPC correction process” may be referred to as “read error data”. Furthermore, “a read error sector that cannot be corrected by the LDPC correction process” may be referred to as “a read error sector”.

The ECC unit 630 executes the process of correcting errors in data based on the Error Correction Code (hereinafter may be referred to as ECC processing). The ECC unit 630 executes the ECC processing based on ECC corresponding to each track per track. Based on the parity data, parity sector, or parity code corresponding to a particular area, the ECC unit 630 performs ECC processing of the data in this area. For example, based on the parity data, parity sector, or parity code corresponding to a particular track, the ECC unit 630 performs the ECC processing of the read error sector or read error data of this particular track. For example, the ECC unit 630 performs the ECC processing of the read error sector or read error data of this particular track based on the parity data, parity sector, or parity code corresponding to this particular track generated based on the parity data, parity sector, or parity code corresponding to another track different from the particular track. The ECC unit 630 records or logs the information of the sector in which the ECC processing is performed (hereinafter may be referred to as ECC sector information) in a particular recording area, such as disk 10, volatile memory 70, or nonvolatile memory 80.

The reassign control unit 640 reassigns (or performs reassigning process of) a particular area, for example, a sector or data. The reassign or reassigning process includes the process of writing data written to a particular area to another area, that is, the process of replacing, rearranging, or copying (duplicating) a particular sector with another sector. The reassign control unit 640 reassigns sectors of no good quality (hereinafter may be referred to as low-quality sectors). For example, the reassign control unit 640 reassigns sectors which have been subjected to the ECC processing. The sectors which have been subjected to the ECC processing may have lower quality than sectors have not been subjected to the ECC processing. Hereinafter, “the sector which has been subjected to the ECC processing” may be referred to as “a low quality sector”. Based on the ECC sector information, the reassignment control part 640 reassigns a particular low-quality sector of a particular track in the user data region 10a to a particular area in the disk 10, for example, the media cache 10b or the system area 10c.

The parity sector management unit 650 calculates parity data by executing an exclusive logical OR (Exclusive OR: XOR) operation, and manages the calculated parity data and the parity sector in which the parity data is written. The parity data corresponds to, for example, the parity bit and the parity detection code. The parity sector management unit 650 calculates the parity data by performing XOR operation of the data in a particular area, and writes the calculated parity data to a particular sector of the particular area (hereinafter may be referred to as the parity sector). Hereinafter, “calculating the parity data and writing the calculated parity data to the parity sector” may be referred to as “generating the parity sector”.

The parity sector management unit 650, for example, performs XOR operation of all sectors of a particular track to generate a parity sector for the track. The parity sector management unit 650, for example, performs XOR operation of all sectors of other tracks that are different from the particular track and generates a parity sector for the other tracks. The parity sector management unit 650, for example, performs XOR operation of partial sectors of a particular track to generate a parity sector on the track. The parity sector management unit 650, for example, performs XOR operation of partial sectors of a particular track to generate parity sectors on other tracks different from the track. The parity sector management unit 650 generates a parity sector on this particular track by performing an XOR operation on partial sectors of the particular track and partial sectors of other tracks that are different from the track.

For example, the parity sector management unit 650 generates a parity sector (hereinafter may be referred to as reassigned parity sector) in the reassigned track by performing XOR operation of at least one low-quality sector (hereinafter may be referred to as reassigned sector) reassigned from a particular track (hereinafter may be referred to as source track) to a track different from the source track (hereinafter referred to as reassigned track).

For example, the parity sector management unit 650 generates at least one reassigned sector that is reassigned to a reassigned track into a reassigned parity sector on a track different from the reassigned track (may be referred to as parity track) by performing an XOR operation.

For example, the parity sector management unit 650 generates a parity sector (hereinafter may be referred to as source parity sector) in the source track by performing XOR operation of at least one reassigned sector that is reassigned from the source track to the reassigned track and at least one sector that is not reassigned in the source track (hereinafter may be referred to as non-reassigned sector).

For example, the parity sector management unit 650 performs an XOR operation between the reassigned parity sector and at least one non-reassigned sector that is not reassigned on a particular track to generate the source parity sector on the source track.

FIG. 5 is a schematic diagram of an example of the ECC processing method for track TRbcn according to the present embodiment. In the circumferential direction, the direction in which data is written and read is referred to as traveling direction. For example, the traveling direction is opposite to the rotation direction of the disk 10. Note that, the traveling direction and the rotation direction of the disk 10 may be the same. FIG. 5 illustrates a track TRan in the user data region 10a and a track TRbcn in the media cache 10b or the system area 10c. The track TRan corresponds to the source track, and the track TRbcn corresponds to the reassigned track. Note that track TRbcn may be arranged in the user data region 10a. In FIG. 5, for convenience of explanation, tracks TRan and TRbcn are depicted as rectangular shapes extending in the circumferential direction with a particular track width, but in reality, they are curved along the circumferential direction. Furthermore, the tracks TRan and TRbcn may also be wavy, extending in the circumferential direction while varying in the radial direction.

In FIG. 5, the track TRan includes sectors SC0, SC1, SC2, SC3, SC4, SC5, . . . , SCn−4, SCn−3, SCn−2, SCn−1, and SCn, and source parity sector P0. The sectors SC0, SC1, SC2, SC3, SC4, SC5, . . . , SCn−4, SCn−3, SCn−2, SCn−1, and SCn, and the source parity sector P0 are arranged consecutively in the traveling direction in this order. In track TRan, the sector SC1 is adjacent to the traveling direction of the sector SC0, the sector SC2 is adjacent to the traveling direction of the sector SC1, the sector SC3 is adjacent to the traveling direction of the sector SC2, the sector SC4 is adjacent to the traveling direction of the sector SC3, and the sector SC5 is adjacent to the traveling direction of sector SC4. Sector SCn−4 is located in the traveling direction of sector SC5. Sector SCn−3 is adjacent to the traveling direction of the sector SCn−4, the sector SCn−2 is adjacent to the traveling direction of the sector SCn−3, and the sector SCn−1 is adjacent to the traveling direction of the sector SCn−2, and the sector SCn is adjacent to the traveling direction of the sector SCn−1. In the track TRan in FIG. 5, the sector SC0 corresponds to the first sector, for example. In the track TRan of FIG. 5, the source parity sector P0 is adjacent to the traveling direction of sector SCn. In the track TRan of FIG. 5, the source parity sector P0 corresponds to the last sector. For example, the sector SC0 and the source parity sector P0 are adjacent to each other in the circumferential direction. For example, the sector SC0 is adjacent to the source parity sector P0 in the traveling direction. In the track TRan of FIG. 5, the sectors SC0, SC1, SC4, SCn−3, and SCn correspond to low-quality sectors. Furthermore, in the track TRan of FIG. 5, sectors SC2, SC3, SC5, . . . , SCn−4, SCn−2, and SCn−1 correspond to non-reassigned sectors.

In FIG. 5, the track TRbcn includes the sectors SC0, SC1, SC4, SCn−3, SCn, and the reassigned parity sector P1. The sectors SC0, SC1, SC4, SCn−3, SCn, and the reassigned parity sector P1 are aligned consecutively in the traveling direction in this order. In the track TRbcn, the sector SC1 is adjacent to the traveling direction of the sector SC0, the sector SC4 is adjacent to the traveling direction of the sector SC1, the sector SCn−3 is adjacent to the traveling direction of the sector SC4, and the sector SCn is adjacent to the traveling direction of the sector Cn−3. In the track TRbcn of FIG. 5, the reassigned parity sector P1 is adjacent to the traveling direction of sector SCn. In the track TRbcn of FIG. 5, the sectors SC0, SC1, SC4, SCn−3, and SCn correspond to the reassigned sectors.

In the example illustrated in FIG. 5, the system controller 130 reads the sectors SC0 to SCn in the traveling direction and performs XOR operation on the sectors SC0 to SCn to generate the source parity sector P0. The system controller 130 detects the sectors SC0, SC1, SC4, SCn−3, and SCn as read error sectors and performs ECC correction processing on the sectors SC0, SC1, SC4, SCn−3, and SCn based on the source parity sector P0. The system controller 130 records the sectors SC0, SC1, SC4, SCn−3, and SCn as ECC sector information in a particular recording area, such as disk 10, volatile memory 70, or nonvolatile memory 80.

In the example of FIG. 5, the system controller 130 reassigns the sectors SC0, SC1, SC4, SCn−3, and SCn to track TRbcn by referring to the ECC sector information. When the system controller 130 reassigns the sectors SC0, SC1, SC4, SCn−3, and SCn to track TRbcn, the system controller 130 writes the bit strings of sectors SC0, SC1, SC4, SCn−3, and SCn in track TRan (or the location information such as logical block address: LBA) to track TRbcn with the same bit sequence (or location information such as LBA) as the bit sequence of the sectors SC0, SC1, SC4, SCn−3, and SCn in track TRan. When reassigning sectors SC0, SC1, SC4, SCn−3, and SCn to track TRbcn, the system controller 130 writes the sectors SC0, SC1, SC4, SCn−3, and SCn consecutively to track TRbcn in this order.

In the example illustrated in FIG. 5, the system controller 130 reads sectors SC0, SC1, SC4, SCn−3, and SCn in the traveling direction on the track TRbcn and performs XOR operation on sectors SC0, SC1, SC4, SCn−3, and SCn to generate (or write) reassign the parity sector P1 to the adjacent sectors in the traveling direction of sector SCn.

In the example illustrated in FIG. 5, when the system controller 130 performs the ECC processing of sectors SC0, SC1, SC4, SCn−3, and SCn of track TRbcn, the system controller 130 performs the ECC processing of the sectors SC0, SC1, SC4, SCn−3, and SCn of track Rbcn based on the reassigned parity sector P1.

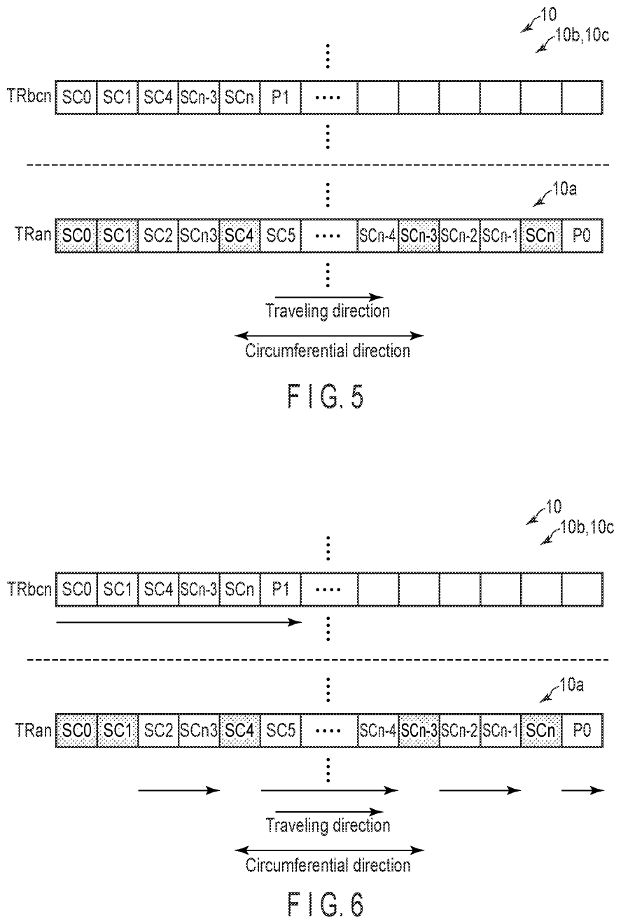

FIG. 6 is a schematic diagram of the ECC processing method for the track Tran according to the present embodiment. FIG. 6 corresponds to FIG. 5. In FIG. 6, for convenience of explanation, tracks TRan and TRbcn are shown as rectangular shapes extending in the circumferential direction with a particular track width, but in reality, they may be curved along the circumferential direction. The tracks TRan and TRbcn may also be wavy, extending in the circumferential direction while varying in the radial direction.

In the example illustrated in FIG. 6, the system controller 130 reads the reassigned sectors SC0, SC1, SC4, SCn−3, and SCn and the reassigned parity sector P1 in track TRbcn toward the traveling direction, and performs XOR operations on the sectors SC0, SC1, SC4, SCn−3, and SCn other than the reassigned parity sector P1 to generate the reassigned parity sector P1. After reading the reassigned sectors SC0, SC1, SC4, SCn−3, and SCn and the reassigned parity sector P1 in the traveling direction in track TRbcn, the system controller 130 reads the sectors SC2, SC3, SC5, . . . , SCn−4, SCn−2, SCn−1 and the source parity sector P0 in the traveling direction, and performs an XOR operation on sectors SC0, SC1, SC4, SCn−3, and SCn other than the reassigned parity sector P1, and sectors SC2, SC3, SC5, . . . , SCn−4, SCn−2, and SCn−1 other than source parity sector P0 to generate the source parity sector P0.

In the example illustrated in FIG. 6, when the system controller 130 performs the ECC processing of the track TRan, the system controller 130 performs the ECC processing of the track TRan based on the source parity sector P0.

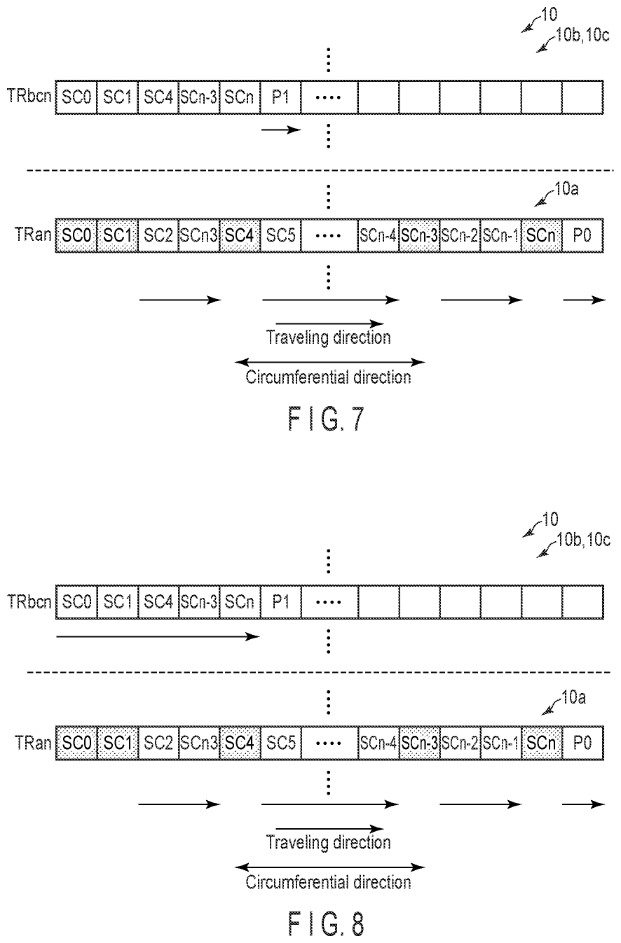

FIG. 7 is a schematic diagram of the ECC processing method for the track TRan according to the present embodiment. FIG. 7 corresponds to FIG. 5. In FIG. 7, for convenience of explanation, the tracks TRan and TRbcn are shown as rectangular shapes extending in the circumferential direction with a particular track width, but in reality, they are curved along the circumferential direction. Furthermore, the tracks TRan and TRbcn may also be wavy, extending in the circumferential direction while varying in the radial direction.

In the example illustrated in FIG. 7, the system controller 130 reads the reassigned parity sector P1 on track TRbcn, and reads not-reassigned sectors SC2, SC3, SC5, . . . , SCn−4, SCn−2, SCn−1, and the source parity sector P0 in the traveling direction, and performs the XOR operation on the sectors SC2, SC3, SC5, . . . , SCn−4, SCn−1, and SCn−1 other than the reassigned parity sector P1 and the source parity sector P0 to generate the source parity sector P0.

In the example of FIG. 7, when the system controller 130 performs the ECC processing of the track TRan, the system controller 130 performs the ECC processing of the track TRan based on the source parity sector P0.

FIG. 8 is a schematic diagram of the ECC processing method for the track TRan according to the present embodiment. FIG. 8 corresponds to FIG. 5. In FIG. 8, for convenience of explanation, the tracks TRan and TRbcn are shown as rectangular shapes extending in the circumferential direction with a particular track width, but in reality, they are curved along the circumferential direction. Furthermore, the tracks TRan and TRbcn may also be wavy, extending in the circumferential direction while varying in the radial direction.

In the example of FIG. 8, the system controller 130 reads the reassigned sectors SC0, SC1, SC4, SCn−3, and SCn in track TRbc, and reads the non-reassigned sectors SC2, SC3, SC5 SC3, SC5, . . . , SCn−4, SCn−2, SCn−1 and the source parity sector P0 in track TRbc, and performs the XOR operation on the sectors SC2, SC3, SC5, . . . , SCn−4, SCn−2, SCn−1 and sectors SC0, SC1, SC4, SCn−3, SCn other than the source parity sector P0 in track TRbc to generate the source parity sector P0.

In the example of FIG. 8, when the system controller 130 performs the ECC processing of the track TRan, the system controller 130 performs the ECC processing of the track TRan based on the source parity sector P0.

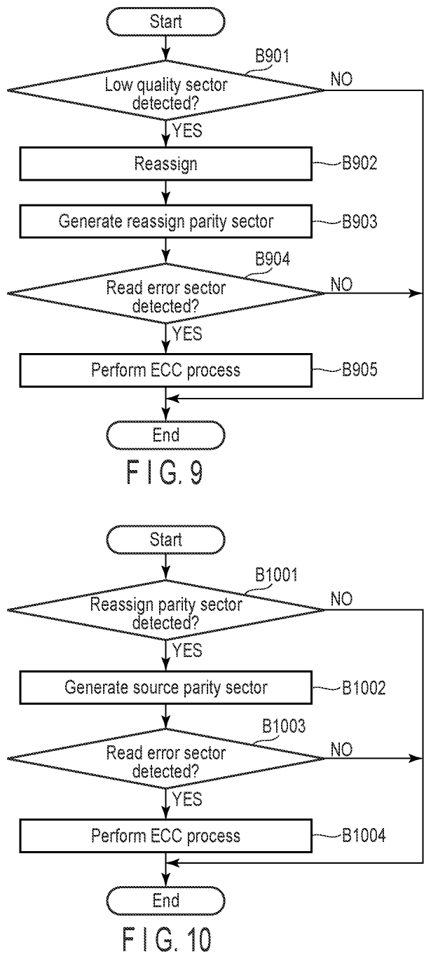

FIG. 9 is a flowchart of an example of the ECC processing method for a reassigned track according to the present embodiment.

The system controller 130 refers to the ECC sector information corresponding to the source track to determine whether or not there is a low-quality sector in the source track (B901). If it is determined that there are no low-quality sectors (NO in B901), the system controller 130 terminates the process. If the system controller 130 determines that there is a low-quality sector (YES in B901), the system controller 130 reassigns the low-quality sector to the reassigned track (B902). The system controller 130 performs XOR operation on the reassigned sector that is reassigned from the source track to the reassigned track to generate the reassigned parity sector in the reassigned track (B903). The system controller 130 determines whether the reassigned track has a read error sector or no read error sector (B904). If it is determined that there is no read error sector (NO in B904), the system controller 130 terminates the process. If it is determined that there is a read error sector (YES of B904), the system controller 130 performs the ECC processing on the read error sector of the reassigned track based on the reassigned parity sector (B905), and terminates the process.

FIG. 10 is a flowchart showing an example of the ECC processing method for a source track according to the present embodiment.

The system controller 130 determines whether or not there is a reassigned parity sector in the reassigned track (B1001). If it is determined that there is no reassigned parity sector (NO in B1001), the system controller 130 terminates the process. If it is determined that there is a reassigned parity sector (YES in B1001), the system controller 130 uses the reassigned parity sector to generate the source parity sector (B1002). The system controller 130 determines whether the source track has a read error sector or no read error sector (B1003). If it is determined that there is no read error sector (NO in B1003), the system controller 130 terminates the process. If it is determined that there is a read error sector (YES of B1003), the system controller 130 performs the ECC processing on the read error sector of the source track based on the source parity sector (B1004) and terminates the process.

According to the first embodiment, the magnetic disk device 1 reassigns the low-quality sectors of the source track to the reassigned track. The magnetic disk device 1 performs the XOR operation on the reassigned sectors reassigned to the reassigned track to generate the reassigned parity sectors on the reassigned track. The magnetic disk device 1 can correct the reassigned sector of the reassigned track of disk 10, e.g., media cache 10b or system area 10c, based on the reassigned parity sector. Furthermore, if a plurality of reassigned tracks are arranged consecutively in the radial direction of the disk 10, e.g., media cache 10b of the system area 10c, the magnetic disk device 1 can reduce track pitches of the reassigned tracks, or can perform the shingled magnetic recording of the reassigned tracks. Therefore, the magnetic disk device 1 can improve the disk 10, for example, BPI (bits per inch) and TPI (tracks per inch). Thus, the magnetic disk device 1 can improve the reliability.

Now, a magnetic disk device of an embodiment other than the aforementioned first embodiment, and a magnetic disk device of a modification will be explained. In the other embodiments and other variations, the same components as in the first embodiment will be referred to by the same reference numbers, and the description thereof will be omitted.

(Modification 1)

In modification 1, a magnetic disk device 1 differs from the magnetic disk device 1 of the first embodiment described above in a method of generating a reassigned parity sector.

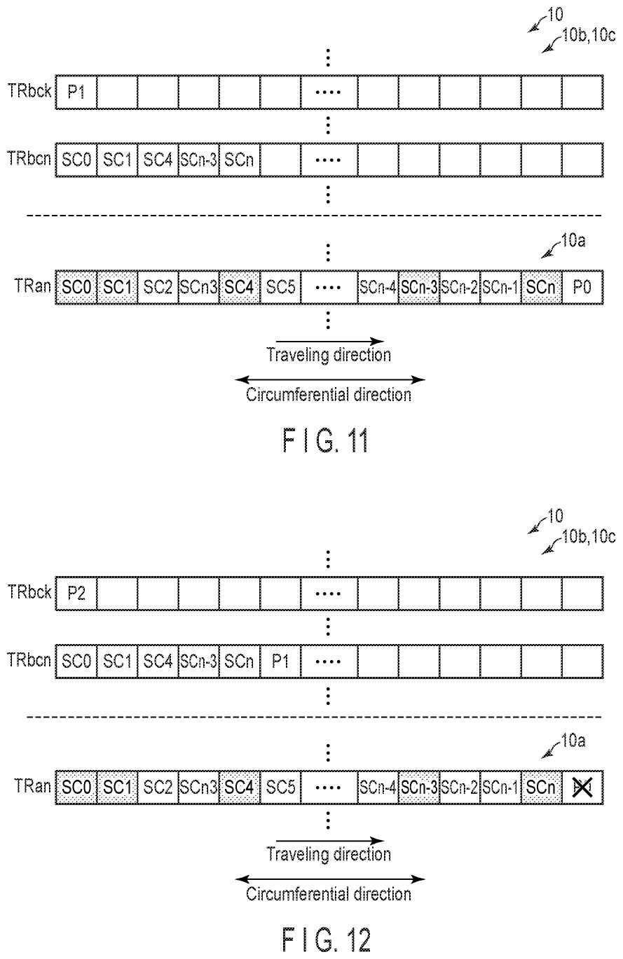

FIG. 11 is a schematic diagram of an example of a generating method for a reassigned parity sector P1 according to modification 1. FIG. 11 corresponds to a part of FIG. 5. FIG. 11 further illustrates a track TRbck located in a media cache 10b or a system area 10c. The track TRbck corresponds to the parity track. In FIG. 11, for convenience of explanation, tracks TRan, TRbcn, and TRbck are shown as rectangular shapes extending in a circumferential direction with a particular track width, but in reality, they are curved along the circumferential direction. Furthermore, the tracks TRan, TRbcn, and TRbck may be wavy, extending out in the circumferential direction while varying in the radial direction.

In the example illustrated in FIG. 11, the system controller 130 reads sectors SC0, SC1, SC4, SCn−3, and SCn in the traveling direction on track TRbcn, and performs an XOR operation on the sectors SC0, SC1, SC4, SCn−3, and SCn to generate (or write) a reassigned parity sector P1 on the track TRbck.

In the example of FIG. 11, when the system controller 130 performs the ECC processing of the sectors SC0, SC1, SC4, SCn−3, and SCn of the track TRbcn, the system controller 130 performs the ECC processing of the sectors SC0, SC1, SC4, SCn−3, and SCn of TRbcn based on the reassigned parity sector P1 written to the track TRbck.

According to Modification 1, the magnetic disk device 1 generates a reassigned parity sector on a parity track different from the reassigned track by performing the XOR operation of the reassigned sector reassigned on the reassigned track. The magnetic disk device 1 can correct the reassigned sector of the reassigned track based on the reassigned parity sector of the track. Therefore, the magnetic disk device 1 can improve the reliability.

### Second Embodiment

The magnetic disk device 1 of the second embodiment generates a parity sector corresponding to a non-reassigned sector, and in this respect, it differs from the first embodiment and Modification 1 described above.

The system controller 130 generates a parity sector (may be referred to as a non-reassigned parity sector) on a parity track by performing an XOR operation on at least one non-reassigned sector of a source track. In other words, the system controller 130 generates a non-reassigned parity sector on a parity track by performing an XOR operation on a non-reassigned sector that could be corrected by at least one LDPC correction process of a source tracks. Note that the system controller 130 may generate non-reassigned parity sectors on tracks other than the parity track by performing XOR operations on the non-reassigned sectors that could be corrected by at least one LDPC correction process of the source track.

FIG. 12 is a schematic diagram of an example of a generating method for a non-reassigned parity sector P2 according to the second embodiment. FIG. 12 corresponds to a part of FIG. 5 and FIG. 11. In FIG. 12, for convenience of explanation, tracks TRan, TRbcn, and TRbck are shown as rectangular shapes extending in the circumferential direction with a particular track width, but in reality, they are curved along the circumferential direction. Furthermore, the tracks TRan, TRbcn, and TRbck may be wavy, extending out in the circumferential direction while varying in the radial direction.

In the example of FIG. 12, the system controller 130 reassigns sectors SC0, SC1, SC4, SCn−3, and SCn to track TRbcn by referring to the ECC sector information. When reassigning sectors SC0, SC1, SC4, SCn−3, and SCn to track TRbcn, the system controller 130 may write sectors SC0, SC1, SC4, SCn−3, and SCn of the same bit sequence (or location information such as LBA) as that of sectors SC0, SC1, SC4, SCn−3, and SCn in track TRan to track TRbcn, or may write sectors SC0, SC1, SC4, SCn−3, and SCn of the bit sequence (or location information such as LBA) different from that of sectors SC0, SC1, SC4, SCn−3, and SCn of track Tran to track TRbcn.

In the example of FIG. 12, the system controller 130 reads sectors SC0, SC1, SC4, SCn−3, and SCn in the traveling direction on track TRbcn and performs an XOR operation on sectors SC0, SC1, SC4, SCn−3, and SCn to generate (or write) a reassigned parity sector P1 to the adjacent sectors in the traveling direction of the sector SCn.

In the example of FIG. 12, the system controller 130 reads sectors SC2, SC3, SC5, . . . , SCn−4, SCn−2, and SCn−1 in the traveling direction in track IRAN, and performs XOR operation on sectors SC2, SC3, SC5, . . . , SCn−4, SCn−2, and SCn−1 in the track TRan to generate (or write) a non-reassigned parity sector P2 in the parity track TRbck.

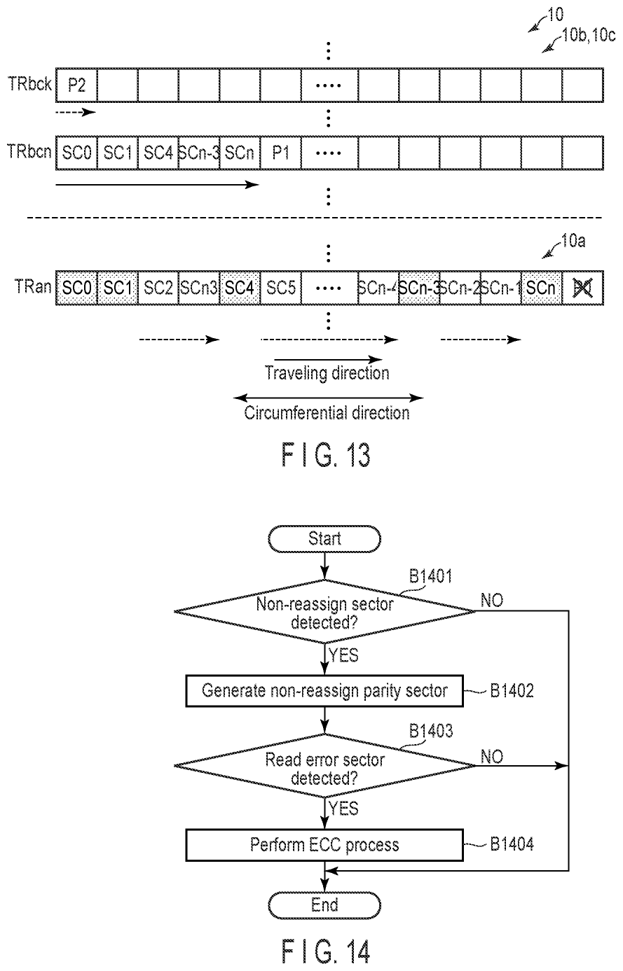

FIG. 13 is a schematic diagram of the ECC processing method for tracks TRbcn and TRan according to the second embodiment. FIG. 13 corresponds to FIG. 12. In FIG. 13, for convenience of explanation, tracks TRan, TRbcn, and TRbck are shown as rectangular shapes extending in a circumferential direction with a particular track width, but in reality, they are curved along the circumferential direction. Furthermore, the tracks TRan, TRbcn, and TRbck may be wavy, extending out in the circumferential direction while varying in the radial direction.

When the system controller 130 performs the ECC processing on track TRbcn, the system controller 130 performs the ECC processing on track TRbcn based on the reassigned parity sector P1.

When performing the ECC processing on a track TRan, the system controller 130 performs the ECC processing on the track TRan based on the non-reassigned parity sector P2.

FIG. 14 is a schematic diagram showing a flowchart of an example of the ECC processing method for source tracks according to the second embodiment.

The system controller 130 determines whether the source track has a non-reassigned sector or not (B1401). If it is determined that there are no non-reassigned sectors (NO in B1401), the system controller 130 terminates the process. If it is determined that there is a non-reassigned sector (YES in B1401), the system controller 130 generates a non-reassigned parity sector in the parity track by performing an XOR operation on the non-reassigned sectors of the source track (B1402). The system controller 130 determines whether the non-reassigned sector of the source track has a read error sector or no read error sector (B1403). If it is determined that there is no read error sector (NO in B1403), the system controller 130 terminates the process. If it is determined that there is a read error sector (YES of B1403), the system controller 130 performs the ECC processing on the read error sector within the non-reassigned sector of the source track based on the non-reassigned parity sector (B1404) and terminates the process.

According to the second embodiment, the magnetic disk device 1 generates a non-reassigned parity sector on the parity track. The magnetic disk device 1 can correct the non-reassigned sector of the source track of disk 10, e.g., user data region 10a, based on the non-reassigned parity sector. The magnetic disk device 1 can manage the reassigned sector and the non-reassigned sector separately. Thus, magnetic disk device 1 can achieve improving the reliability thereof.

Some examples of a magnetic disk device and an error correction method achieved from the present embodiment will be noted below.

(1) A magnetic disk device comprising:

a disk including a first area where user data is written and a second area which is different from the first area;

a head configured to write data to the disk and read data from the disk; and

a controller configured to generate, when a first sector of a first track, which includes a first parity sector and the first sector which is different from the first parity sector in the first area, is reassigned to a second track in the second area, a second parity sector corresponding to the first sector.

(2) The magnetic disk device of (1), wherein the controller writes the second parity sector to the second track.

(3) The magnetic disk device of (1), wherein the controller writes the second parity sector to a third track which is different from the second track in the second area.

(4) The magnetic disk device of any one of (1) to (3), wherein the controller performs error correction of the first sector of the second track based on the second parity sector.

(5) The magnetic disk device of any one of (1) to (4), wherein the controller generates the first parity sector based on the first sector and sectors other than the first parity sector of the first track, and the second parity sector.

(6) The magnetic disk device of (5), wherein the controller performs error correction of the first track based on the first parity sector.

(7) The magnetic disk device of (1) or (2), wherein the controller generates a third parity sector based on the first sector and sectors other than the first parity sector of the first track.

(8) The magnetic disk device of (7), wherein the controller writes the third parity sector to a third track which is different from the second track of the second area.

(9) The magnetic disk device of (7) or (8), wherein the controller performs error correction of the first sector and sectors other than the first parity sector of the first track based on the third parity sector.

(10) The magnetic disk device of any one of (7) to (9), wherein the first sector and the sectors other than the first parity sector of the first track correspond to sectors corrected through LDPC.

(11) The magnetic disk device of any one of (1) to (10), wherein the first sector corresponds to a sector which has not been corrected through LDPC but is corrected through ECC.

(12) The magnetic disk device of any one of (1) to (11), wherein the controller writes data in shingled magnetic recording by which a plurality of tracks overlapping in a radial direction of the disk are written in the first area, and writes data in conventional magnetic recording by which a plurality of tracks are written in the radial direction of the disk at intervals.

(13) An error correction method which is applied to a magnetic disk device including a disk with a first area where user data is written and a second area which is different from the first area, and a head configured to write data to the disk and to read data from the disk, the method comprising:

generating, when a first sector of a first track, which includes a first parity sector and the first sector which is different from the first parity sector in the first area, is reassigned to a second track in the second area, a second parity sector corresponding to the first sector.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic disk device comprising:
a disk including a first area where user data is written and a second area which is different from the first area;
a head configured to write data to the disk and read data from the disk; and
a controller configured to generate, when a first sector of a first track, which includes a first parity sector and the first sector which is different from the first parity sector in the first area, is reassigned to a second track in the second area, a second parity sector corresponding to the first sector.

2. The magnetic disk device of claim 1, wherein the controller writes the second parity sector to the second track.

3. The magnetic disk device of claim 1, wherein the controller writes the second parity sector to a third track which is different from the second track in the second area.

4. The magnetic disk device of claim 1, wherein the controller performs error correction of the first sector of the second track based on the second parity sector.

5. The magnetic disk device of claim 1, wherein the controller generates the first parity sector based on the first sector and sectors other than the first parity sector of the first track, and the second parity sector.

6. The magnetic disk device of claim 5, wherein the controller performs error correction of the first track based on the first parity sector.

7. The magnetic disk device of claim 1, wherein the controller generates a third parity sector based on the first sector and sectors other than the first parity sector of the first track.

8. The magnetic disk device of claim 7, wherein the controller writes the third parity sector to a third track which is different from the second track of the second area.

9. The magnetic disk device of claim 7, wherein the controller performs error correction of the first sector and sectors other than the first parity sector of the first track based on the third parity sector.

10. The magnetic disk device of claim 7, wherein the first sector and the sectors other than the first parity sector of the first track correspond to sectors corrected through LDPC.

11. The magnetic disk device of claim 1, wherein the first sector corresponds to a sector which has not been corrected through LDPC but is corrected through ECC.

12. The magnetic disk device of claim 1, wherein the controller writes data in shingled magnetic recording by which a plurality of tracks overlapping in a radial direction of the disk are written in the first area, and writes data in conventional magnetic recording by which a plurality of tracks are written in the radial direction of the disk at intervals.

13. An error correction method which is applied to a magnetic disk device including a disk with a first area where user data is written and a second area which is different from the first area, and a head configured to write data to the disk and to read data from the disk, the method comprising:
generating, when a first sector of a first track, which includes a first parity sector and the first sector which is different from the first parity sector in the first area, is reassigned to a second track in the second area, a second parity sector corresponding to the first sector.

14. The error correction method of claim 13, further comprising:
writting the second parity sector to the second track.

15. The error correction method of claim 13, further comprising:
writting the second parity sector to a third track which is different from the second track in the second area.

16. The error correction method of claim 13, further comprising:
performing error correction of the first sector of the second track based on the second parity sector.

17. The error correction method of claim 13, further comprising:
generating the first parity sector based on the first sector and sectors other than the first parity sector of the first track, and the second parity sector.

18. The error correction method of claim 17, further comprising:
performing error correction of the first track based on the first parity sector.

19. The error correction method of claim 13, further comprising:
generating a third parity sector based on the first sector and sectors other than the first parity sector of the first track.

20. The error correction method of claim 19, further comprising:
writting the third parity sector to a third track which is different from the second track of the second area.
